(19) United States
(12) Patent Application Publication
(10) Pub. No.: US 2026/0119766 A1
(43) Pub. Date: Apr. 30, 2026

(54) IMPLEMENTATION METHOD AND SYSTEM FOR BARE METAL FPGA SERVER

(71) Applicant: INSTITUTE OF COMPUTING TECHNOLOGY, CHINESE ACADEMY OF SCIENCES, Beijing (CN)

(72) Inventors: Yisong CHANG, Beijing (CN); Fanzhang PENG, Beijing (CN); Liuhao SHAN, Beijing (CN); Ke ZHANG, Beijing (CN); Yungang BAO, Beijing (CN)

(21) Appl. No.: 19/142,007

(22) PCT Filed: Mar. 16, 2023
(86) PCT No.: PCT/CN2023/081842

§ 371 Date: Jun. 20, 2025

(30) Foreign Application Priority Data
Dec. 23, 2022 (CN) 202211667411.7

(51) Int. Cl. G06F 30/343

(52) U.S. Cl. CPC G06F 30/343

(57) ABSTRACT

In order to solve the problem in existing low-level I/O peripheral abstraction method for cloud FPGAs that limits flexibility of cloud FPGAs'resource management and tenant usage, this invention introduces an implementation method and system of an FPGA bare metal server, in which the cloud FPGAs are treated as the first-class computing resources in the same manner of the general x86 host. Without customizing and developing new system component, the complexity of managing cloud FPGAs is reduced. Meanwhile, tenants are allowed to directly apply for, deploy and leverage the FPGA bare metal host in a pay-as-you-go manner without applying for additional general computing resources.

### CROSS-REFERENCE TO RELATED APPLICATIONS

This application is the U.S. National Stage entry of International Application No. PCT/CN2023/081842, filed on Mar. 16, 2023, which, in turn, claims priority to CN Patent Application No. 202211667411.7, filed on Dec. 23, 2022, both of which are hereby incorporated herein by reference in their entireties for all purposes.

### BACKGROUND OF THE INVENTION

### 1. Field of the Invention

The invention relates to the technical field of cloud computing and the technical field of data center system architecture that supports heterogeneous FPGA acceleration, and particularly, relates to an implementation method and system for an FPGA bare metal FPGA server.

### 2. Related Art

Field Programmable Gate Arrays (FPGAs) are a kind of specialized hardware programmable chips. According to application requirements, users may independently design their custom hardware logic architectures, and program (configure) and deploy such designs into FPGA chips for accelerated application processing performance. Meanwhile, with a specialized and simplified hardware architecture compared with the conventional Von Neumann computer system architecture, domain-specific accelerators implemented in the FPGA are expected to ensure low energy consumption overhead, enhance an energy efficiency ratio of the application, and to flexibly and efficiently break through “performance walls” and “energy consumption walls” faced in existing application processing.

In 2014, Microsoft deployed and leveraged FPGAs in its in-house data centers to accelerate Web searching services, prompting many cloud vendors to deploy FPGAs in data centers to accelerate their cloud applications. As the deployment of FPGAs continuously increasing in the data center, cloud vendors are exposing FPGAs as public rentable computing resources for tenants in a pay-as-you-go manner. In 2016, Amazon AWS exhibited rentable FPGA computing instances for cloud tenants to deploy custom application accelerators; leading other cloud vendors (e.g., Alibaba Cloud, Tencent, Huawei, etc.) launched cloud FPGA infrastructure and publicly available services.

FIG. 1 is a schematic diagram of cloud FPGA architecture based on the in-chassis PCI-Express (PCIe) in the prior art. In existing public cloud environment, abstract description of cloud FPGAs is ordinarily performed in the form of I/O devices attached to the standard PCI Express (PCIe) bus via physical or virtual functions for either resource provisioning or accelerator deployment.

In the existing mainstream public cloud environment, an abstract description of the cloud FPGA resources is still performed in the form of I/O devices, causing cloud vendor management and tenant usage of the cloud FPGA resources to face the following problems:
1) Cloud FPGA hardware cards are managed in the form of secondary resources of general resources such as x86 servers (including physical machines or virtual machines). A working state and a running state of the cloud FPGA cards are deeply bound to the x86 servers, causing that the cloud resource management platform cannot directly acquire device state information of the FPGA board cards, and a dedicated component of FPGA device management shall be additionally customized in the framework of cloud platform resource management,, increasing development cost of the cloud FPGA resource management system.
2) The tenant shall apply for a general x86 cloud host for deployment, control and access of its PCIe-attached cloud FPGAs. The tenant cannot directly and flexibly access such heterogeneous FPGA acceleration resources in the same way of accessing the general cloud computing resources.

Specifically, management and usage of the cloud FPGA resources include:
1) Cloud resource management (management plane): by abstracting FPGAs as the conventional PCIe-attached I/O peripherals, the general x86 server physical machine manages all its visible cloud FPGA cards; in the use process, several cloud FPGA hardware board cards are bound to a virtual machine of one cloud tenant through I/O virtualization techniques (such as, PCIe Pass-through) of the x86 server physical machine. In this manner, the tenant is allowed to access FPGA programmable logic resources in a virtual machine context.
2) FPGA hardware programming configuration (management plane): the FPGA hardware logic resources are divided into a static region and a dynamic region. The static region comprises series of fixed hardware logic blocks, e.g., a memory controller, a PCIe interface controller and other I/O peripheral interfaces. The dynamic region is configured to deploy ‘tenants’ application accelerators, and may be dynamically reconfigured according to needs of the cloud tenant. When performing cloud FPGA hardware programming configuration, the cloud tenant applies to the cloud FPGA administrator for transmission of the configuration bitstream files of the dynamic region. The cloud administrator performs dynamic reconfigurable programming on the dynamic region of the cloud FPGA through a PCIe-based FPGA configuration interface (such as, Xilinx Virtual Cable, i.e., XVC) provided by the FPGA manufacturer.
3) Tenant's application acceleration (data plane): in the x86 virtual machine, the cloud tenant transmits the raw data to be processed to the device memory of the cloud FPGA card through a PCIe virtual function interface and its associated FPGA driver. Meanwhile, the tenant accesses a memory-mapped I/O register provided by the FPGA through the PCIe virtual function interface, and initiates the deployed application accelerator in the FPGA dynamic region to start processing on the raw data. After application processing is completed, the FPGA hardware logic notifies the tenant application running on the x86 virtual machine via interrupt or I/O notification registers to allow the application to read back computing results from the device memory on the cloud FPGA board card.

### SUMMARY OF THE INVENTION

An object of the invention is to solve the problem that an abstract description method for cloud FPGA resources in the prior art is only considered from I/O external devices, causing a low level of abstract description, and limiting flexibility of cloud FPGA resource management and tenant usage mode, and the invention provides a method of abstractly describing FPGA in the public cloud as a bare metal server resource, such that the cloud FPGA resource and the x86 cloud host have a method of general cloud computing resource with similar usage mode, 1) it is unnecessary to customize and develop new cloud FPGA resource management components, simplify the cloud FPGA resource management method, and reduce complexity of resource management; 2) the cloud tenant directly applies for, deploys and uses the FPGA host on demand without applying for general computing resources such as x86 bare metal servers or virtual machines, which is a feasible way of enhancing cloud FPGA management and use flexibility, and reducing dependence on the general x86 computing resources.

Specifically, the invention provides an implementation method for an FPGA bare metal server, comprising:
step 1, constructing a cloud server system with a baseboard management controller (BMC) and a plurality of attached bare metal FPGA cards working as bare metal servers ;
step 2, constructing a device driver layer for starting the FPGA board cards for the baseboard management controller, exposing a kernel mode device object located in an operating system of the baseboard management controller to a user interface, and encapsulating as a service program daemon residing to run in the background of the operation system to timely receive and process resource control requests of an upper management software;
step 3, presenting the bare metal server to the upper resource management software of the baseboard management controller in the form of a network URL address using RESTful APIs, and encapsulating operations of the FPGA board cards as specific attributes under the URL address; and
step 4, uploading imageimage files for FPGA logic configuration bitstream to an imageimagestorage system, and completing power-on of the bare metal server through the URL address, wherein the bare metal server after power-on reads and executes the imageimage files from the imageimage storage system to complete the FPGA logic configuration, and the client transfers a computing task and desired data to the bare metal server through data network, and starts computing components on the bare metal server through the network to begin running so as to obtain execution results.

In the implementation method for an FPGA bare metal server, the FPGA board cards are FPGA board cards having standard PCIe interfaces, the step 4 comprising:
the image files being bitstream image files, by modifying the management software running on the baseboard management controller, completing power-on of the bare metal server through the URL address, the software of the baseboard management controller configuring the bitstream image files in a dynamic region of the corresponding bare metal server through a PCIe device driver, and setting a management register between the FPGA dynamic region and static region of the bare metal server to be a working state so that the FPGA board card of the bare metal server enters into the working state;
when the task is completed, the client completing power-off of the bare metal server through the URL address.

In the implementation method for an FPGA bare metal server, the FPGA board cards are private SoC-FPGA board cards designed with self-defined interfaces, the step 4 comprising:
the image files being bitstream image files, the client uploading the bitstream image files as installed initrd into the image storage system of a cloud computing management platform;
by modifying the management software running on the baseboard management controller, providing URL set in a start mode for each bare metal server managed by the baseboard management controller;
setting the start mode to NETWORK startup through a POST method provided by the URL; when the URL in the corresponding start mode of the bare metal server managed by the baseboard management controller is set to be a “NETWORK” character string, the baseboard management controller modifying BIOS EEPROM corresponding to a node of the bare metal server;
the client performing power-on operation on the bare metal server, the baseboard management controller directly controlling a power management interface of the bare metal server through a GPIO device driver to power on the bare metal server; the bare metal server after power-on starting according to setting of BIOS EEPROM, and automatically grabbing and running the installed initrd;
according to the installed initrd, directly writing the task file to be installed into the storage system on the bare metal server; after writing is completed, modifying the start mode to local, and restarting the bare metal server;
after the bare metal server restarts, automatically loading the task file from the storage system of the local bare metal server; when the task is completed, the client completing power-off of the bare metal server through the URL address.

In the implementation method for an FPGA bare metal server, the computing task is an FPGA supportable acceleration application, comprising deep neural network, data encryption/decryption and data compression/decompression task.

The invention further provides an implementation system for an FPGA bare metal server, comprising:
an initial module for constructing a cloud server system formed of a baseboard management controller and a plurality of bare metal servers connected thereto, the bare metal servers comprising FPGA board cards;
a start module for constructing a device driver layer for starting the FPGA board cards for the baseboard management controller, exposing a kernel mode device object located in an operation system of the baseboard management controller to a user interface, and encapsulating as a service program daemon residing to run in the background of the operation system to timely receive and process resource control requests of an upper management software;
a configuration module for presenting the bare metal server to the upper resource management software of the baseboard management controller in the form of a network URL address using a RESTful interface, and encapsulating operations of the FPGA board cards as specific attributes under the URL address; and
a running module for uploading image files for FPGA logic configuration to a image storage system, and completing power-on of the bare metal server through the URL address, wherein the bare metal server after power-on reads and executes the image files from the image storage system to complete the FPGA logic configuration, and the client transfers a computing task and desired data to the bare metal server through data network, and starts computing components on the bare metal server through the network to begin running so as to obtain execution results.

In the implementation system for an FPGA bare metal server, the FPGA board cards are FPGA board cards having standard PCIe interfaces, the running module comprising:
the image files being bitstream image files, by modifying the management software running on the baseboard management controller, completing power-on of the bare metal server through the URL address, the software of the baseboard management controller configuring the bitstream image files in a dynamic region of the corresponding bare metal server through a PCIe device driver, and setting a management register between the FPGA dynamic region and static region of the bare metal server to be a working state so that the FPGA board card of the bare metal server enters into the working state;
when the task is completed, the client completing power-off of the bare metal server through the URL address.

In the implementation system for an FPGA bare metal server, the FPGA board cards are private SoC-FPGA board cards designed with self-defined interfaces, the running module comprising:
the image files being bitstream image files, the client uploading the bitstream image files as installed initrd into the image storage system of a cloud computing management platform;
by modifying the management software running on the baseboard management controller, providing URL set in a start mode for each bare metal server managed by the baseboard management controller;
setting the start mode to NETWORK startup through a POST method provided by the URL; when the URL in the corresponding start mode of the bare metal server managed by the baseboard management controller is set to be a “NETWORK” character string, the baseboard management controller modifying BIOS EEPROM corresponding to a node of the bare metal server;
the client performing power-on operation on the bare metal server, the baseboard management controller directly controlling a power management interface of the bare metal server through a GPIO device driver to power on the bare metal server; the bare metal server after power-on starting according to setting of BIOS EEPROM, and automatically grabbing and running the installed initrd;
according to the installed initrd, directly writing the task file to be installed into the storage system on the bare metal server; after writing is completed, modifying the start mode to local, and restarting the bare metal server;

After the bare metal server restarts, automatically loading the task file from the storage system of the local bare metal server; when the task is completed, the client completing power-off of the bare metal server through the URL address.

In the implementation system for an FPGA bare metal server, the computing task is an FPGA supportable acceleration application, comprising deep neural network, data encryption/decryption and data compression/decompression task.

The invention further provides a storage medium for storing programs executing any of the implementation method for an FPGA bare metal server.

The invention further provides a client for any of the implementation system for an FPGA bare metal server.

As can be known from the above solution, the advantages of the invention are as follows:

To solve the problem that the existing cloud FPGA resources can be only used as secondary resources of I/O external devices, the invention provides a method of enhancing cloud FPGA abstract description level, which converts the heterogeneous FPGA resources into bare metal cloud server resources having the same standard interfaces as the x86 general computing resources. By improving the abstraction level of the heterogeneous computing resources, it is possible to:
1) the FPGA heterogeneous computing resources and the x86 general computing resources have the same interface view, and the heterogeneous FPGA resources may be managed using the existing general x86 bare metal server management interfaces without customizing and developing new cloud FPGA resource management components.
2) the FPGA heterogeneous computing resources may be used as independent cloud hosts for the cloud tenant to apply for directly and may provide services to the tenant without dependence on the x86 general computing resources; and may allow the user to deploy and program through simple function expansion of the resource management interfaces.

### BRIEF DESCRIPTION OF THE DRAWINGS

FIG. 1 is a schematic diagram of a PCIe-based FPGA cloud environment architecture in the prior art.

FIG. 2 is an abstract block diagram of cloud service of the prior art.

FIG. 3 is an abstract block diagram of cloud service of the invention.

FIG. 4 is an abstract block diagram of a chassis level.

FIG. 5 is an architecture diagram of a software stack designed on a BMC.

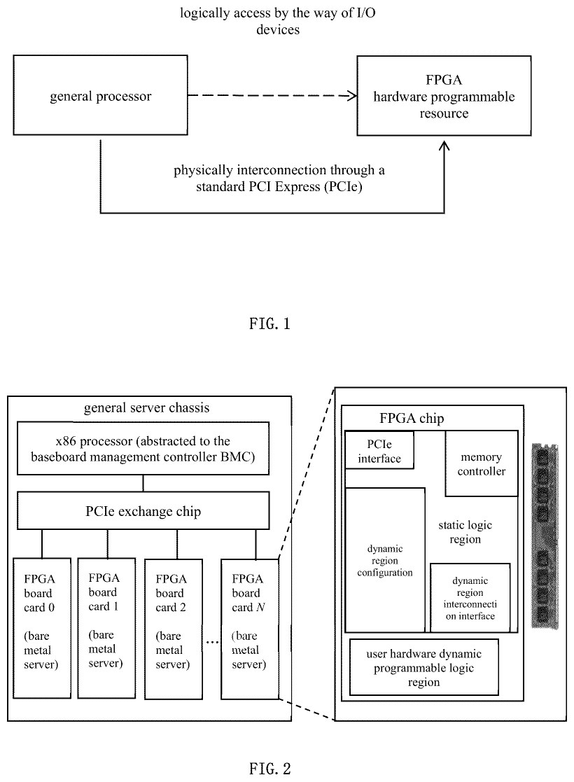

### PREFERABLE EMBODIMENTS OF THE INVENTION

Management and tenant usage mode of the cloud FPGA resources in the prior art lack flexibility, and cannot be compatible with management and usage mode of the general cloud computing resources (e.g., x86 servers). The core of the produced problem is that since an abstract description method for the existing cloud FPGA resources is only considered from I/O external devices, the FPGA is used as secondary computing resources of the general cloud server, thereby limiting the cloud FPGA resources like x86 servers as first class computing resources sharable by the public cloud computation. At current stage, the reason why the cloud FPGA can only be used as the secondary computing recourses of the x86 general cloud server is still to follow the traditional usage mode of the FPGA in the non-cloud computing environment, and complete FPGA programming deployment and application processing only through connection with the x86 servers or the PC computers while not providing a new abstract way of FPGA resources for the new application scenario of the cloud and data center.

When designing and constructing self-developed FPGA cloud computing platform and customizing self-developed FPGA cloud server system structure, the inventor finds out that the key to solve that the existing cloud FPGA resources can can be only used as the secondary resources of the I/O external devices is to enhance cloud FPGA abstract level, and abstractly describe the FPGA as bare metal cloud server resources. The traditional FPGA resources cannot be abstracted into one type of independent machines (no matter whether it is a virtual machine or a bare metal server) in the original mode, but only I/O devices attached to the machine. The idea of the invention is to directly use the FPGA as a machine on the cloud, i.e., a bare metal server (a physical server on the cloud), for resource management and use. The FPGA bare metal server may reduce management overhead, so that the cloud resource administrator uses the same interfaces as the general computing resources for management without developing additional FPGA resource management software.

By improving abstract level of the heterogeneous computing resources, it is possible to:
1) the FPGA heterogeneous computing resources and the x86 general computing resources have the same interface view, and the heterogeneous FPGA resources may be managed using the existing general x86 bare metal server management interfaces without customizing and developing new cloud FPGA resource management components.
2) the FPGA heterogeneous computing resources may be used as independent cloud hosts for the cloud tenant to apply for directly, and may provide services to the tenant without dependence on the x86 general computing resources; and may allow the user to deploy and program through simple function expansion of the resource management interfaces.

Specifically, the application includes the following key technical points:
Key point 1: a bare metal cloud server abstract description method for cloud FPGA resources may implement remote management and state monitoring on the cloud FPGA resources through two levels of abstract, i.e., host (system) and chassis (chassis);
Key point 2: a flow method for remote management of the FPGA bare metal server (e.g., power-on and power-off operations on the cloud FPGA board cards, hardware programming, installation of operation system, etc.) provide standard access interfaces for the use to remotely deploy and use the cloud FPGA.

To enable the above features and effects of the invention to set forth clearer, hereinafter the embodiments are listed, and detailed descriptions are made with reference to the accompanying drawings.

### 1. FPGA Bare Metal Cloud Server Abstract Method

First, the invention provides a method of separating a management plane and a data plane of the cloud FPGA, breaking the situation that the management plane and the data plane of the existing FPGA resources are all tightly coupled to a PCIe physical interface, and alleviating absolute dependence of the cloud resource management and application acceleration process on the x86 general computing resources. The method decouples the cloud FPGA resource management and data interaction to different physical interfaces through physically and completely isolated control plane and data plane hardware interfaces, thereby providing physical support for decoupling of the resource management and data interaction planes.

The invention is suitable for cloud environments such as FPGA public cloud environment (FPGA board cards having standard PCIe interfaces), FPGA cloud designed with self-defined interfaces, and specific embodiments include:

With respect to the existing FPGA public cloud environment, the standard PCIe bus (and matched I2C bus) interface may be used as a control plane physical interface of the cloud FPGA, and only relevant operations of FPGA resource management, configuration management and state monitoring may be processed. Meanwhile, the existing cloud FPGA often has a high-speed Ethernet interface, and forms auxiliary interconnection independent of PCIe through a network switch. Accordingly, the invention uses the standard Ethernet interconnection interface as a data plane physical interface, thereby separating the data plane physical interface from the control plane physical interface.

As for the FPGA cloud server designed with self-defined interface (e.g., IBM cloudFPGA and the granted patent ZL2020100190139), the self-defined interface (including interface connection such as power management interface, I2C bus, etc.) may be used as the control plane physical interface of the cloud FPGA. Meanwhile, high-speed Ethernet channel (such as, IBM cloudFPGA) or an on-chip interconnection interface (e.g., the patent ZL2020100190139) of SoC-FPGA tightly-coupled chip (such as, Xilinx Zynq series FPGA chip) may be used as the data plane interface.

On such basis, the invention provides abstracting a general processor used by the control plane physical interface as a baseboard management controller (BMC), and may deploy general or custom BMC baseboard management software (such as, open source baseboard management software OpenBMC). Specific implementations include:

With respect to the existing FPGA public cloud environment, the general x86processor may be used as the BMC, which manages and deploys cloud FPGA board card within a chassis of the same physical server. As shown in FIG. 2, the invention abstracts the x86processor to the baseboard management controller (BMC), implements state monitoring and resource management of different FPGA board cards downwardly through the PCIe, and provides RESTful API interface upwardly (cloud resource management framework).

As for the FPGA cloud server designed with self-defined interface (e.g., the granted patent ZL2020100190139), the SoC-FPGA tightly-coupled chip used on a baseboard and controlled by the self-defined interface may be used as the BMC, which manages nodes of all cloud FPGA board cards in the FPGA cloud server.

Secondly, based on the separated control plane and the BMC abstract, the invention further provides a cloud FPGA bare metal server abstract description method for cloud FPGA physical board cards managed by the BMC in the baseboard management software running in the BMC, particularly comprising:

Host (Systems) level abstract: describing basic attributes of cloud FPGA bare metal server host running independently, including processing unit situation, memory sotiatopm, power supply state/operation, start mode and the like. With respect to different types of cloud FPGA chips and board card types, specific abstract ways are as follows:
1. With respect to pure FPGA chip and board cards used in the existing FPGA public cloud environment, the cloud FPGA bare metal server may be distinguished using different PCIe bus device numbers visible to BMC.

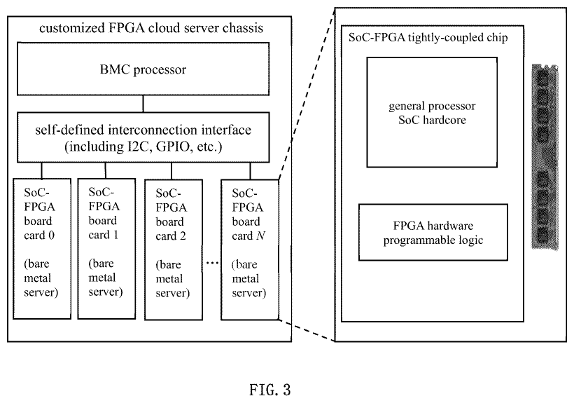

The difficulty of bare metal server abstract for the pure FPGA chips and board cards is to represent programming configuration situation of the FPGA hardware resources by using the power supply state. Performing power-on operation on the bare metal server host represents performing dynamic reconfigurable programming of the FPGA dynamic region through the PCIe interface of the BMC host, and enabling management interface (such as, Xilinx Partial Reconfiguration Decoupler) between the FPGA dynamic region and static region. Performing power-off operation on the bare metal server host represents closing the management interface between the FPGA dynamic region and static region through the PCIe interface of the BMC host, such that the dynamic region enters into a reset state, and application acceleration processing is no longer performed.
2. With respect to the FPGA cloud server designed with the self-defined interfaces (e.g., the granted patent ZL2020100190139), the BMC may distinguish and manage nodes of the SoC-FPGA board cards in the cloud server using the self-defined physical interface. Based on the self-defined management interface, power-on and power-off management of the SoC-FPGA bare metal server may be implemented through the GPIO control software in the baseboard management controller BMC, as shown in FIG. 3.

The difficulty of bare metal server abstract for the SoC-FPGA board cards is also how to perform dynamic reconfigurable configuration of the FPGA dynamic region using the baseboard management software BMC. The invention may configure the start way of the SoC-FPGA bare metal server to network startup through EEPROM read-write driver and application interface through the baseboard management software BMC. In the start process, the installation agent operation system image running on the SoC-FPGA is cooperated with the installation flow provided by the OpenStack Ironic resource management framework to perform partial reconfigurable configuration of the FPGA dynamic region. After the user completes use of it, the SoC-FPGA may be powered off directly through power-on and power-off management interface of the BMC to invalid configuration of the current FPGA dynamic region. Specific process of the dynamic reconfigurable configuration of the FPGA dynamic region includes:
1. Cloud resource management framework (e.g., OpenStack) may remotely control one SoC-FPGA board card (i.e., nodes of one bare metal server) through an access interface provided by the baseboard management software BMC.
2. Cloud resource management framework sets the start state of the SoC-FPGA board card to network startup through the access interface.
3. After the SoC-FPGA board card starts, the SoC part loads the installation agent operation system image from the network and runs it. After running, it communicates with the cloud resource management framework through the network.
4. Cloud resource management framework transmits bitstream files in the dynamic region to the installation operation system.
5. After receiving complete bitstream files, the installation operation system writes bitstream in the dynamic region into the FPGA dynamic region to complete reconfigurable configuration through SoC-FPGA configuration interface (e.g., Xilinx MCAP interface) driver.

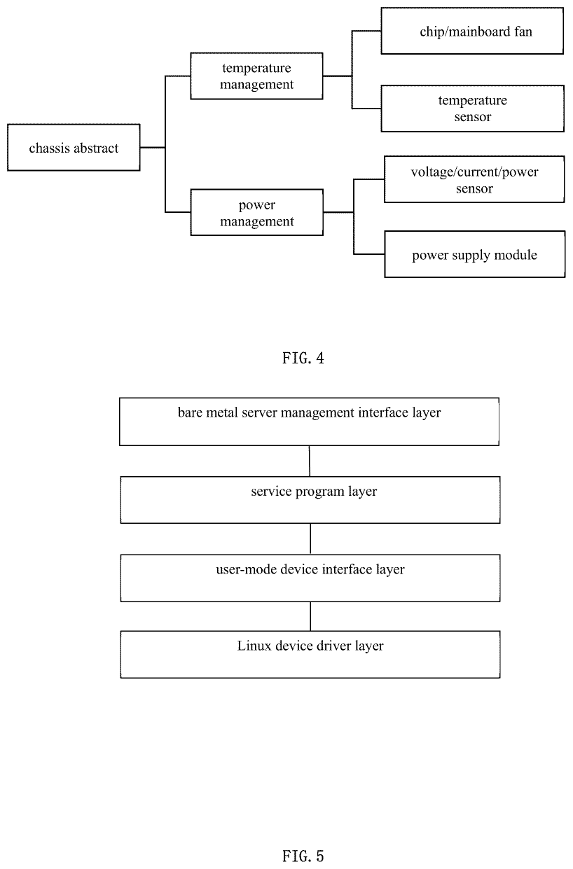

Chassis-level abstract: as shown in FIG. 4, it describes working states of hardware board cards of the cloud FPGA bare metal server, including index values such as voltage, current, power, power management, temperature, fan speed and the like of the server, and a sensor hardware or circuit board-level module for managing and monitoring these working states. As for the existing FPGA public cloud or self-defined FPGA cloud server, the BMC may control the sensor or hardware circuit module through an I2C software and hardware access interface.

2. Cloud management flow of the FPGA bare metal server. To implementing cloud management of the FPGA bare metal server resources, it is necessary to design a software stack architecture shown in FIG. 5 on the abstracted baseboard management controller BMC of the invention, particularly comprising

Linux device driver layer: software running on the baseboard management controller BMC. The BMC itself does not know that it manages nodes of one FPGA board card, so the FPGA is not sensed. The Linux device driver layer is configured to manage key hardware components that start and run the cloud FPGA hardware board card, specifically including power management module (PCIe device driver or GPIO device driver) of the FPGA board card, hardware resources (I2C device driver) such as temperature/electrical sensors of the FPGA board card, FPGA startup BIOS storage medium (I2C EEPROM device driver), FPGA hardware logic programming configuration interface (GPIO device driver), and the like.

User-mode device interface layer: exposing the kernel mode device object located in the BMC operation system to the user interface for use of upper applications through the sysfs file system or specialized device access library function (e.g., libgpiod) of Linux.

Service program layer: further encapsulating a peripheral access interface exposing the user-mode device interface layer to be a service program daemon residing to run in the background of the operation system to timely receive and process resource control requests of an upper management software.

Bare metal server management interface layer: using a management and control RESTful interface provided by the management software running on the baseboard management controller BMC to the cloud resource management framework (e.g., OpenStack), presenting the bare metal server to the upper resource management software of the BMC in the form of a network URL address (e.g., https://IP address/Systems/bare metal server ID No.); encapsulating key operations such as power-on and power-off of the FPGA board cards as one specific attribute (e.g., https://IP address/Systems/bare metal server ID No./Actions/ComputerSystem. Reset) under the URL address, and modifying the attribute value through a POST method provided by the RESTful interface to control the bare metal server, wherein POST is an API of the RESTful interface for updating resource attributes or creating new resources.

On such basis, combining with OpenStack Ironic bare metal server deployment interface, specific software and hardware deployment and installation interfaces and flows are implemented for different types of FPGA clouds:

With respect to pure FPGA chips and board cards used in the existing FPGA public cloud environment, start flows of the hardware programming configuration of the bare metal server are as follows:
1. The user uploads bitstream image files to be configured into the image storage system of OpenStack through OpenStack management interface. The bitstream files are responsible for FPGA logic configuration. Specific computing tasks may begin running by transferring, via the user, raw data desired by the computing tasks to the FPGA through data network, and starting computing components on the FPGA through the network. The running computing tasks include various types of acceleration applications, such as FPGA supportable acceleration applications like deep neural network, data encryption/decryption and data compression/decompression.
2. The management software running on the BMC (x86 server physical CPU) is modified to provide URL (https://IP address/Systems/bare metal server ID No./Actions/BootSource) set in a start mode for each FPGA bare metal server managed by the BMC.

The OpenStack Ironic bare metal server management framework may set the start mode through the POST method provided by the above URL, and the default set value is “BIT” character string. When the URL in the start mode corresponding to one FPGA bare metal server managed by the BMC is set to be “BIT” character string, the BMC voluntarily launches an access request to the OpenStack image storage system, and stores the bitstream configuration files pre-uploaded in step 1 to a fixed path of the BMC file system.
3. The user may perform power-on operation on the FPGA bare metal server whose start mode has been modified in step 2 through the OpenStack Ironic bare metal server management framework (executing POST operation on http://IP address/Systems/bare metal server ID No./Actions/ComputerSystem. Reset, and writing a character string “On”). At this time, the BMC software acquires the bitstream files acquired in step 2, configures in the dynamic region of the corresponding FPGA bare metal server through the PCIe device driver, and sets a management register between the FPGA dynamic region and static region to be a working state so that the FPGA enters into a normal working state of application acceleration.
4. After the application acceleration task stops, the user may perform power-off operation on the OpenStack Ironic bare metal server management framework (executing POST operation on https://IP address/Systems/bare metal server ID No./Actions/ComputerSystem. Reset, and writing a character string “ForceOff”). After receiving a power-off command, the BMC sets the management register between the FPGA dynamic region and static region to be a closed state through the PCIe interface, thereby resetting the dynamic region, and no longer performing application acceleration processing.

With respect to the FPGA cloud server designed with self-defined interfaces (e.g., the granted patent ZL2020100190139), flows of the bare metal server remote operation system software deployment startup facing tightly-coupled SoC-FPGA chips and board cards and the FPGA hardware programming configuration are as follows:
1. The user uploads the operation system image files to be deployed into the OpenStack image storage system through the OpenStack management interface; meanwhile, sets OpenStack Ironic network installation service image (installation initrd).
2. Modifying the management software running on the BMC chip on the custom cloud server host provides URL (https://IP address/Systems/bare metal server ID No./Actions/BootSource) set in a start mode for each FPGA bare metal server managed by the BMC.

The OpenStack Ironic bare metal server management framework may set the start mode to a character string “NETWORK” (i.e., network startup) through the POST method provided by the above URL. When the URL in the start mode corresponding to one FPGA bare metal server managed by the BMC is set to be the character string “NETWORK”, the BMC modifies BIOS EEPROM corresponding to a node of the SoC-FPGA bare metal server.
3. The user may perform power-on operation on the FPGA bare metal server whose start mode has been modified in step 2 through the OpenStack Ironic bare metal server management framework controller (Conductor) of (executing POST operation on http://IP address/Systems/bare metal server ID No./Actions/ComputerSystem. Reset, and writing a character string “On”). At this time, the BMC directly controls a power management interface of the SoC-FPGA bare metal server through the GPIO device driver, so that the SoC-FPGA bare metal server is powered on. After power-on, the SoC-FPGA bare metal server automatically grabs and starts to run the deployed installation initrd in step 1 from network startup according to the start mode set in the BIOS EEPROM in step 2, and after starting, automatically connects with the OpenStack Ironic controller.
4. The OpenStack Ironic controller directly controls the installation initrd running on the SoC-FPGA bare metal server, and directly writes the operation system image to be installed into a storage system (such as, NVMe SSD hard disk) on the SoC-FPGA bare metal server through the remote copy. After writing is completed, the user modifies the start mode (https://IP address/Systems/bare metal server ID No./Actions/BootSource) to “LOCAL” through the OpenStack Ironic controller, and restarts the bare metal server (executing POST operation on https://IP address/systems/bare metal server Id No./Actions/ComputerSystem. Reset, and writing a character string “ForceReset”).
5. After the bare metal server restarts, the operation system deployed and installed in the storage system in step 4 is automatically loaded, and network services are started. The tenant may directly access the rented and deployed bare metal server through the network.
6. During use of the tenant, the tightly-coupled FPGA hardware logic may be dynamically configured in the SoC partially running operation system of the bare metal server.
7. The user may perform power-off operation through the OpenStack Ironic bare metal server management framework (executing POST operation on https://IP address/Systems/bare metal server ID No./Actions/ComputerSystem. Reset, and writing a character string “ForceOff”). After receiving a power-off command, the BMC directly controls a power management interface of the SoC-FPGA bare metal server through the GPIO device driver so that the SoC-FPGA bare metal server is powered off.

Hereinafter is a system embodiment corresponding to the above-mentioned method embodiments, and this embodiment may be implemented in cooperation with the above embodiments. Relevant technical details mentioned in the above embodiments are still effective in this embodiment, and in order to reduce repetition, no details are described here. Correspondingly, relevant technical details mentioned in this embodiment also may be applied to the above embodiments.

The invention further provides an implementation system for an FPGA bare metal server, comprising:
an initial module for constructing a cloud server system formed of a baseboard management controller and a plurality of bare metal servers connected thereto, the bare metal servers comprising FPGA board cards;
a start module for constructing a device driver layer for starting the FPGA board cards for the baseboard management controller, exposing a kernel mode device object located in an operation system of the baseboard management controller to a user interface, and encapsulating as a service program daemon residing to run in the background of the operation system to timely receive and process resource control requests of an upper management software;
a configuration module for presenting the bare metal server to the upper resource management software of the baseboard management controller in the form of a network URL address using a RESTful interface, and encapsulating operations of the FPGA board cards as specific attributes under the URL address; and
a running module for uploading image files for FPGA logic configuration to a image storage system, and completing power-on of the bare metal server through the URL address, wherein the bare metal server after power-on reads and executes the image files from the image storage system to complete the FPGA logic configuration, and the client transfers a computing task and desired data to the bare metal server through data network, and starts computing components on the bare metal server through the network to begin running so as to obtain execution results.

In the implementation system for an FPGA bare metal server, the FPGA board cards are FPGA board cards having standard PCIe interfaces, the running module comprising:
the image files being bitstream image files, by modifying the management software running on the baseboard management controller, completing power-on of the bare metal server through the URL address, the software of the baseboard management controller configuring the bitstream image files in a dynamic region of the corresponding bare metal server through a PCIe device driver, and setting a management register between the FPGA dynamic region and static region of the bare metal server to be a working state so that the FPGA board card of the bare metal server enters into the working state;
when the task is completed, the client completing power-off of the bare metal server through the URL address.

In the implementation system for an FPGA bare metal server, the FPGA board cards are private SoC-FPGA board cards designed with self-defined interfaces, the running module comprising:
the image files being bitstream image files, the client uploading the bitstream image files as installed initrd into the image storage system of a cloud computing management platform;
by modifying the management software running on the baseboard management controller, providing URL set in a start mode for each bare metal server managed by the baseboard management controller;
setting the start mode to NETWORK startup through a POST method provided by the URL; when the URL in the corresponding start mode of the bare metal server managed by the baseboard management controller is set to be a “NETWORK” character string, the baseboard management controller modifying BIOS EEPROM corresponding to a node of the bare metal server;
the client performing power-on operation on the bare metal server, the baseboard management controller directly controlling a power management interface of the bare metal server through a GPIO device driver to power on the bare metal server; the bare metal server after power-on starting according to setting of BIOS EEPROM, and automatically grabbing and running the installed initrd;
according to the installed initrd, directly writing the task file to be installed into the storage system on the bare metal server; after writing is completed, modifying the start mode to local, and restarting the bare metal server;
after the bare metal server restarts, automatically loading the task file from the storage system of the local bare metal server; when the task is completed, the client completing power-off of the bare metal server through the URL address.

In the implementation system for an FPGA bare metal server, the computing task is an FPGA supportable acceleration application, comprising deep neural network, data encryption/decryption and data compression/decompression task.

The invention further provides a storage medium for storing programs executing any of the implementation method for an FPGA bare metal server.

The invention further provides a client for any of the implementation system for an FPGA bare metal server.

### INDUSTRIAL APPLICABILITY

The invention provides an implementation method and system for an FPGA bare metal server, comprising: constructing a cloud server system formed of a baseboard management controller and a plurality of bare metal servers connected thereto, the bare metal servers comprising FPGA board cards; constructing a device driver layer for starting the FPGA board cards for the baseboard management controller, exposing a kernel mode device object located in an operation system of the baseboard management controller to a user interface, and encapsulating as a service program daemon residing to run in the background of the operation system to timely receive and process resource control requests of an upper management software; presenting the bare metal server to the upper resource management software of the baseboard management controller in the form of a network URL address using a RESTful interface, and encapsulating operations of the FPGA board cards as specific attributes under the URL address; and uploading image files for FPGA logic configuration to a image storage system, and completing power-on of the bare metal server through the URL address, wherein the bare metal server after power-on reads and executes the image files from the image storage system to complete the FPGA logic configuration, and the client transfers a computing task and desired data to the bare metal server through data network, and starts computing components on the bare metal server through the network to begin running so as to obtain execution results.

The invention directly uses the FPGA as a machine on the cloud, i.e., a bare metal server (a physical server on the cloud), for resource management and use. The FPGA bare metal server may reduce management overhead, so that the cloud resource administrator uses the same interface as that of the general computing resource for management without developing additional FPGA resource management software.

1. An implementation method for bare metal FPGA server, comprising:
step 1, constructing a cloud server system formed of a baseboard management controller and a plurality of bare metal servers connected thereto, the bare metal servers comprising FPGA board cards;
step 2, constructing a device driver layer for starting the FPGA board cards for the baseboard management controller, exposing a kernel mode device object located in an operation system of the baseboard management controller to a user interface, and encapsulating as a service program daemon residing to run in the background of the operation system to timely receive and process resource control requests of an upper management software;
step 3, presenting the bare metal server to the upper resource management software of the baseboard management controller in the form of a network URL address using a RESTful interface, and encapsulating operations of the FPGA board cards as specific attributes under the URL address; and
step 4, uploading image files for FPGA logic configuration to a image storage system, and completing power-on of the bare metal server through the URL address, wherein the bare metal server after power-on reads and executes the image files from the image storage system to complete the FPGA logic configuration, and the client transfers a computing task and desired data to the bare metal server through data network, and starts computing components on the bare metal server through the network to begin running so as to obtain execution results.

2. The implementation method for a bare metal FPGA server according to claim 1, wherein the FPGA board cards are FPGA board cards having standard PCIe interfaces, the step 4 comprising:
the image files being bitstream image files, by modifying the management software running on the baseboard management controller, completing power-on of the bare metal server through the URL address, the software of the baseboard management controller configuring the bitstream image files in a dynamic region of the corresponding bare metal server through a PCIe device driver, and setting a management register between the FPGA dynamic region and static region of the bare metal server to be a working state so that the FPGA board card of the bare metal server enters into the working state;
when the task is completed, the client completing power-off of the bare metal server through the URL address.

3. The implementation method for a bare metal FPGA server according to claim 1, wherein the FPGA board cards are private SoC-FPGA board cards designed with self-defined interfaces, the step 4 comprising:
the image files being bitstream image files, the client uploading the bitstream image files as installed initrd into the image storage system of a cloud computing management platform;
by modifying the management software running on the baseboard management controller, providing URL set in a start mode for each bare metal server managed by the baseboard management controller;
setting the start mode to NETWORK startup through a POST method provided by the URL; when the URL in the corresponding start mode of the bare metal server managed by the baseboard management controller is set to be a “NETWORK” character string, the baseboard management controller modifying BIOS EEPROM corresponding to a node of the bare metal server;
the client performing power-on operation on the bare metal server, the baseboard management controller directly controlling a power management interface of the bare metal server through a GPIO device driver to power on the bare metal server; the bare metal server after power-on starting according to setting of BIOS EEPROM, and automatically grabbing and running the installed initrd;
according to the installed initrd, directly writing the task file to be installed into the storage system on the bare metal server; after writing is completed, modifying the start mode to local, and restarting the bare metal server;
after the bare metal server restarts, automatically loading the task file from the storage system of the local bare metal server; when the task is completed, the client completing power-off of the bare metal server through the URL address.

4. The implementation method for bare metal FPGA server according to claim 1, wherein the computing task is an FPGA supportable acceleration application, comprising deep neural network, data encryption/decryption and data compression/decompression task.

5. An implementation system for a bare metal FPGA server, comprising:
an initial module for constructing a cloud server system formed of a baseboard management controller and a plurality of bare metal servers connected thereto, the bare metal servers comprising FPGA board cards;
a start module for constructing a device driver layer for starting the FPGA board cards for the baseboard management controller, exposing a kernel mode device object located in an operation system of the baseboard management controller to a user interface, and encapsulating as a service program daemon residing to run in the background of the operation system to timely receive and process resource control requests of an upper management software;
a configuration module for presenting the bare metal server to the upper resource management software of the baseboard management controller in the form of a network URL address using a RESTful interface, and encapsulating operations of the FPGA board cards as specific attributes under the URL address; and
a running module for uploading image files for FPGA logic configuration to a image storage system, and completing power-on of the bare metal server through the URL address, wherein the bare metal server after power-on reads and executes the image files from the image storage system to complete the FPGA logic configuration, and the client transfers a computing task and desired data to the bare metal server through data network, and starts computing components on the bare metal server through the network to begin running so as to obtain execution results.

6. The implementation system for a bare metal FPGA server according to claim 5, wherein the FPGA board cards are FPGA board cards having standard PCIe interfaces, the running module comprising:
the image files being bitstream image files, by modifying the management software running on the baseboard management controller, completing power-on of the bare metal server through the URL address, the software of the baseboard management controller configuring the bitstream image files in a dynamic region of the corresponding bare metal server through a PCIe device driver, and setting a management register between the FPGA dynamic region and static region of the bare metal server to be a working state so that the FPGA board card of the bare metal server enters into the working state;
when the task is completed, the client completing power-off of the bare metal server through the URL address.

7. The implementation system for a bare metal FPGA server according to claim 5, wherein the FPGA board cards are private SoC-FPGA board cards designed with self-defined interfaces, the running module comprising:
the image files being bitstream image files, the client uploading the bitstream image files as installed initrd into the image storage system of a cloud computing management platform;
by modifying the management software running on the baseboard management controller, providing URL set in a start mode for each bare metal server managed by the baseboard management controller;
setting the start mode to NETWORK startup through a POST method provided by the URL; when the URL in the corresponding start mode of the bare metal server managed by the baseboard management controller is set to be a “NETWORK” character string, the baseboard management controller modifying BIOS EEPROM corresponding to a node of the bare metal server;
the client performing power-on operation on the bare metal server, the baseboard management controller directly controlling a power management interface of the bare metal server through a GPIO device driver to power on the bare metal server; the bare metal server after power-on starting according to setting of BIOS EEPROM, and automatically grabbing and running the installed initrd;
according to the installed initrd, directly writing the task file to be installed into the storage system on the bare metal server; after writing is completed, modifying the start mode to local, and restarting the bare metal server;
after the bare metal server restarts, automatically loading the task file from the storage system of the local bare metal server; when the task is completed, the client completing power-off of the bare metal server through the URL address.

8. The implementation system for a bare metal FPGA server according to claim 5, wherein the computing task is an FPGA supportable acceleration application, comprising but not limited to deep neural network, data encryption/decryption and data compression/decompression task.

9. A storage medium for storing programs executing the implementation method for a bare metal FPGA server according to claim 1.

10. (canceled)
